(19) United States
(12) Patent Application Publication
(10) Pub. No.: US 2019/0326487 A1
(43) Pub. Date: Oct. 24, 2019

(54) Platelet for an Optoelectronic Device, Method for Producing an Optoelectronic Device and Optoelectronic Device

(71) Applicant: OSRAM OPTO SEMICONDUCTORS GMBH, Regensburg (DE)

(72) Inventors: Thomas REESWINKEL, Regensburg (DE); Patrick NINZ, Regensburg (DE)

(73) Assignee: OSRAM Opto Semiconductors GmbH, Regensburg (DE)

(21) Appl. No.: 16/317,489

(22) PCT Filed: Jul. 19, 2017
(86) PCT No.: PCT/EP2017/068240

§ 371 Date: Jan. 11, 2019

(30) Foreign Application Priority Data
Jul. 21, 2016 (DE) 10 2016 113 490.2

(51) Int. Cl. H01L 33/56; H01L 33/50; C08J 7/12; C08J 7/06

(52) U.S. Cl. CPC H01L 33/56; H01L 33/502; C08J 7/12; C08J 2383/04; H01L 2933/0091; H01L 2933/005; H01L 2933/0041; C08J 7/065

(57) ABSTRACT

A platelet for an optoelectronic device, a method for producing an optoelectronic device and an optoelectronic device are disclosed. In an embodiment, a platelet includes silicone and chemical compounds located on at least one surface of the platelet, wherein each chemical compound comprises an anchor group and a head group, wherein the chemical compounds are bonded to the silicone by the anchor group, and wherein an adhesion on the at least one surface is reduced by the head groups of the chemical compounds.

This patent application is a national phase filing under section 371 of PCT/EP2017/068240, filed Jul. 19, 2017, which claims the priority of German patent application 102016113490.2, filed Jul. 21, 2016, each of which is incorporated herein by reference in its entirety.

### TECHNICAL FIELD

The invention relates to a platelet for an optoelectronic device, to a method for producing an optoelectronic device and to an optoelectronic device.

### BACKGROUND

Components of optoelectronic devices containing silicone can often be sticky on the surfaces due to the silicone. In the event of high stickiness, for example, with respect to particles from the surroundings or with respect to tools, which come into contact with the components, it can lead to a plurality of problems during the processing of the components and also during operation of the device, into which the components are inserted.

One possibility for reducing the stickiness is a sealing of the silicone surface by a non-adhesive, polymer to vitreous layer by an active deposition by a plasma process. The monomer hexamethyldisiloxane (HMDSO) is used here as the starting material. However, the seal can impair the optical properties such as the brightness or emission characteristic or cause visual changes. Visual changes are, for example, a turbid, milky surface in the case of thicker coatings that can occur in the case of a seal. A thicker coating can additionally alter the dimension of the sealed component. Furthermore, the conventional method or its effect is not reversible, and subsequent removal of the seal is thus not possible.

On the tool side, for example, in the case of a mounting machine, special surfaces such as a teflon coating or a roughening can be used, in order to reduce the adhesion of a sticky silicone surface. As a result, the tool life is considerably reduced.

Furthermore, any residues of materials, for example, casting material, which can arise during the installation of a component in an optoelectronic device on the surface of the component, have to be removed again with great effort.

### SUMMARY OF THE INVENTION

Embodiments provide improved components for optoelectronic devices. Further embodiments provide an optoelectronic device, in which such a component is used, and a method for producing an optoelectronic device containing such a component. Embodiments of the invention relate to a platelet for an optoelectronic device containing a silicone. Chemical compounds are present on at least one surface of the platelet, each comprising an anchor group and a head group, and the chemical compounds are bonded to the silicone by the anchor group. The adhesion on the at least one surface is reduced by the head groups of the chemical compounds.

The platelet has dimensions which enable the platelet to be used in an optoelectronic device. For example, the platelet is dimensioned in such a way that it can be arranged substantially or completely congruently on an active layer stack of an optoelectronic device, for example, a light-emitting diode (LED).

The term “surface” is to be understood here and in the following as a face, which runs along the main extension direction of the platelet and parallel to a second face (a second surface). The two surfaces are connected to one another via side faces arranged perpendicular to the main extension direction. The platelet is thus substantially flat. It is also conceivable for the chemical compounds to be present on both surfaces of the platelet and/or on one, several or all of the side faces.

It is further understood that the anchor group of the chemical compounds, which are present on the at least one surface is bonded to the silicone, which is located on the outer surface of the platelet (in contrast to the silicone present in the interior of the platelet). Therefore, this surface can also be referred to here and in the following as a “silicone surface”.

Here and in the following, adhesion is to be understood as stickiness, in particular an inclination of the silicone surface for the adhesion of particles from the surroundings or of tool surfaces, which are brought into contact with the silicone surface. Particles from the surroundings can, for example, be particles such as they are frequently to be found in industrial production processes, such as, for example, metal dusts or metal chips, ceramic dusts, separated silicone particles, or even normal dust or other impurities. The particle sizes are typically in the micrometer range. Furthermore, adhesion is also to be understood as a good adhesion possibility or wettability for other materials, for example, adhesives.

The inventors of the present invention have recognized that the adhesion properties of platelets containing silicone can be influenced by the bonding of chemical compounds. Chemical compounds comprising an anchor group and a head group are particularly suitable, wherein the head group has properties enabling a reduction in the adhesion, that is to say of the stickiness, while the bonding of the chemical compounds to the silicone surface takes place through the anchor group. The anchor group is therefore bonded to the silicone surface, while the head group is directed outwards, that is to say away from the platelet. By means of such a modified surface of the platelet, its stickiness or adhesion can be significantly reduced.

As a result, the handling of the platelet during its processing is facilitated, in particular during the mounting process in, for example, a vibrating conveyor, sorter or taper, both within the component processing and in the subsequent construction on the customer side. As a result, yields can be increased and production costs can be reduced, in particular since manual intervention is avoided. Even specially adapted tools, which have higher purchase prices and/or lower service lives, are no longer necessary in the case of reduced stickiness of the silicone surfaces brought into contact with them. Due to the reduced adhesion or stickiness on at least one surface of the platelet, lower suction or pressing forces can be applied during mounting, whereby impressions from the tool on the platelets are avoided or reduced.

The platelet can thus be processed internally particularly well by the presence of the chemical compounds and thus of the reduced adhesion to at least one surface, without the occurrence of an optical change due to, for example, such impressions.

If the platelet forms the later outer surface of an optoelectronic device, undesirable particle adhesions, which would lead to uncontrolled changes in the resulting product performance, such as a brightness reduction or a different emission characteristic, can also be prevented or reduced.

Even in the case of an encapsulation of the platelet, after it has been applied to, for example, an active layer stack of an optoelectronic device, undesirable residues from the encapsulation material can be avoided on the surface on which the chemical compounds are present, which would likewise adversely affect the optical properties such as, for example, brightness or the emission characteristic or would lead to undesirable visual changes. The subsequent removal of such residues, which is associated with great effort, can thus be avoided or at least considerably facilitated due to the reduced adhesion.

In addition, the chemical compounds or their head groups can be at least partially removed from the platelet, after it has been inserted into an optoelectronic device. The thus restored adhesion possibility on the surface of the platelet can be used for fixing further components, which are required for the production of the device.

Overall, the materials of the platelet and the chemical compounds arranged thereon can be selected in such a way, in that the properties of the platelet are adapted to its operation site in an optoelectronic device, for example, the adhesion of the silicone of the platelet to a substrate and the stickiness or surface energy of the silicone surface, on which the chemical compounds are arranged.

According to one embodiment of the platelet, the chemical compounds bonded to the silicone by the anchor group form a monomolecular layer. Thus, there is no formation of several superimposed layers of the chemical compounds on the silicone surface.

In this way, particularly thin layers of the chemical compounds of a few nm may be possible on the at least one surface of the platelet, for example, less than 100 nm, in particular less than 50 nm, preferably less than 10 nm, more preferably less than 5 nm, and particularly preferably less than 3 nm. Despite the very thin layer thicknesses, the adhesion to particles or tool surfaces can be significantly reduced. The desired effect can thus be achieved with a small amount of material.

Alternatively or additionally, the thickness of the layer of the chemical compounds can be greater than or equal to 0.5 nm. In this way, it can be avoided that excessively small layer thicknesses reduce the adhesion-reducing effect.

As a result of the formation as a thin monomolecular layer, the chemical compounds also do not or only slightly impair the appearance and the optical properties of the platelet. For example, undesirable changes in the radiation transmissivity or the transparency or a change in the refractive index of silicone can be avoided. The dimensions of the platelet are also not changed by the presence of the chemical compounds on at least one surface, as is the case, for example, with a thicker coating with HMDSO in the case of a sealing.

According to a further embodiment, the chemical compounds bonded to the silicone by the anchor group form a self-assembling monolayer (SAM). By means of a SAM, a layer which shields the sticky silicone surface can be produced. The reduction of the adhesion is particularly effective, the more compact the chemical compounds are arranged. For this purpose, SAMs are very particularly suitable since they have a high degree of order and thus enabling a compact arrangement of the chemical compounds on the silicone surface.

According to a further embodiment, the head group is selected from a group comprising linear alkyl groups, branched alkyl groups, at least partially fluorinated linear alkyl groups, at least partially fluorinated branched alkyl groups, perfluorinated linear alkyl groups and perfluorinated branched alkyl groups.

With linear alkyl groups, linear at least partially fluorinated alkyl groups or linear perfluorinated alkyl groups, the chemical compounds can be arranged in a particularly compact manner on the silicone surface. The more compact the arrangement of the chemical compounds, the more clearly the adhesion can be reduced, for example, to surrounding particles or tool surfaces. Compact SAMs can also be produced particularly well with linear alkyl groups, linear at least partially fluorinated alkyl groups or linear perfluorinated alkyl groups.

Partially fluorinated and perfluorinated head groups lead to a particularly significant reduction in the adhesion. In addition, fluorinated groups have the effect of reducing the coefficient of friction. Friction coefficients represent a measure of the sliding and, in particular, static friction and thus also reflect static or adhesion properties. If the coefficient of friction is reduced, the adhesion of the surface of the platelet is also reduced. Fluorinated head groups can also reduce various types of contamination due to their high both hydrophobic and oleophobic properties. In some cases, even a self-cleaning effect can be possible, by droplets of liquid droplets being able to roll off layers comprising fluorinated head groups and thereby additionally wash off particles.

Branched alkyl groups, branched at least partially fluorinated alkyl groups or branched perfluorinated alkyl groups as head groups likewise reduce the adhesion, wherein the high steric requirement of the branched alkyl groups, branched at least partially fluorinated alkyl groups or branched perfluorinated alkyl groups can be used to cover or shield a wide region of the silicone surface. Thus, fewer chemical compounds may be necessary to reduce the adhesion if branched (fluorinated) alkyl groups are present as a head group than with linear (fluorinated) alkyl groups as the head group.

Alkyl groups, at least partially fluorinated alkyl groups or perfluorinated alkyl groups here and in the following mean groups, in particular with a chain length n of 1≤n≤100, preferably 1≤n≤50, more preferably 1≤n≤20, particularly preferably 1≤n≤10. Further preferred chain lengths are, for example, chain lengths in the range of 2≤n≤20 and 2≤n≤10 and 3≤n≤20 and 3≤n≤10.

Even short alkyl groups, short at least partially fluorinated alkyl groups or short perfluorinated alkyl groups can achieve the desired effect of reducing the adhesion. The shorter the alkyl groups, the thinner the layer formed and the less the desired properties of the platelet are influenced. Furthermore, the chain length n of the alkyl groups, at least partially fluorinated or perfluorinated alkyl groups, can be greater than or equal to 2, in particular greater than or equal to 3, so that the adhesion-reducing effect can be fully effective.

The adhesion can be significantly reduced by the use of head groups comprising fluorinated alkyl groups. The higher the degree of fluorination of the alkyl group, the greater the reduction in adhesion. This effect is particularly effective with perfluorinated alkyl groups of the general formula CₙF₂ₙ₊₁.

For example, the head group can be non-fluorinated, at least partially fluorinated or perfluorinated methyl, ethyl, n-propyl, n-butyl, n-pentyl, n-hexyl, n-heptyl, n-octyl, n-nonyl, n-decyl.

According to a further embodiment, the anchor group of the chemical compounds is bonded to the silicone by a covalent bond. Therefore it is a directional bond, in which the chemical compounds are bond to the silicone surface by chemisorption resulting in a particularly stable connection. The reduction of the adhesion of the silicone surface is thus based on a controlled surface coating of the silicone by covalent bonding or grafting of chemical compounds, in particular molecules of a certain chain length, for changing the surface character.

According to a preferred development of the platelet, the anchor group of the chemical compounds is bond by a covalent bond to chemically active centres on the at least one surface. The chemically active centres can be functional groups on the silicone surface, which are, due to their chemical nature, suitable for forming covalent bonds with the anchor group of the chemical compounds. The configurations of the chemically active centres on the silicone surface can be influenced by various types of pre-treatment of the silicone. Depending on the substrate and the material combination, for example, different types of plasma treatments are conceivable, for example, under low-pressure or atmospheric conditions, using different types of gases or gas mixtures. Wet-chemical pre-treatments or a pre-treatment by UV radiation are also conceivable. In principle, however, it is also possible to use the silicone without pre-treatment.

In principle, all functional groups on the silicone surface are conceivable as active surface centres, which can be linked to a suitable anchor group as a partner. Exemplary, radicals or metastable hydroperoxides can be mentioned. The anchor group can furthermore be an electrophile and the active surface centre on the silicone surface can be a nucleophile and vice versa.

Typical active surface centres on the silicone surface can, for example, be silicone surface-OH (“silicone surface-OH” means hydroxyl groups bonded to the silicone surface; this applies analogously to the further described groups), silicone surface-OOH, but also silicone surface-R^{C}—COOH, wherein R^{C} is a hydrocarbon radical, for example, a methylene radical. Depending on the type of pre-treatment, other groups are also conceivable, e.g., silicone surface-NY₂, where Y═H or alykl (e.g., methyl, ethyl, etc.), after a pre-treatment with an NH₃ plasma (or similar plasmas). In particular, surface centers in form of silicone surface-NH₂ can be formed by pre-treatment with NH₃.

According to a further embodiment of the platelet, the anchor group (3) of the chemical compounds is selected from a group comprising the following compounds:

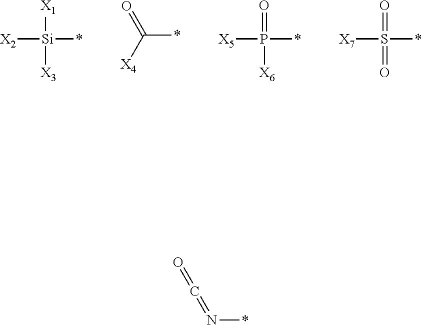

wherein the radicals X₁ to X₃ are selected independently of one another from the group comprising —Cl, —Br, —I, —OH, —OR₁, —H, —R₁, wherein at most two of the radicals X₁ to X₃ may be —H or R₁, wherein R₁ is an alkyl, wherein X₄ is selected from the group comprising —Cl, —Br, —I, —OH, —H, —OSiX₁X₂X₃, wherein X₅, X₆ are selected independently of one another from the group comprising —Cl, —Br, —I, —OH, —OR₁, —H, and wherein X₇ is selected from the group comprising —Cl, —Br, —I, —OH, —OR₁.

R₁ may be an alkyl or a fluorinated alkyl. In particular, R₁ is a short-chain alkyl radical, for example, an alkyl radical of the chain length 1≤n≤7. Particularly preferred are methyl, ethyl, propyl, butyl and pentyl. For example, R₁ is methyl or ethyl.

The symbol “*” stands in each case for the connection point to which the rest of the chemical compound, for example, the head group or a middle group, can be bonded.

The anchor groups shown here can be used, for example, to bond the anchor group to the silicone surface with the formation of acid esters (e.g., carboxylic acid esters, sulfonic acid esters, etc.), but also with the formation of urea derivatives or urethane bonds.

According to a further embodiment, the anchor group is a group of the following general formula:

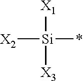

Wherein the radicals X₁ to X₃ are selected independently of one another from the group comprising —Cl, —Br, —I, —OH, —OR₁, —H, —R₁, wherein at most two of the radicals X₁ to X₃ may be —H or R₁, and wherein R₁ is an alkyl.

By using such a silyl anchor, a strong bonding of the chemical compound to the silicone surface can be achieved. Anchor groups of this type in particular form stable covalent bonds with the aforementioned hydroxy groups or hydroperoxy groups (silicone surface-OH, silicone surface-OOH) as chemically active surface centres. In addition, it is possible for a covalent bond to be formed not only between the silyl anchor and the silicone surface, but, depending on the selection of the residues X₁ to X₃, covalent bonds can also be formed between the anchor groups of adjacent chemical compounds, whereby even more stable anchoring can be achieved. This is possible in particular when two or all three of the radicals X₁ to X₃ are selected from —Cl, —Br, —I, —OH, —OR₁.

In a further embodiment, nucleophilic groups, for example, amino groups such as —NH₂, are also possible for the anchor groups. Thus an efficient connection to surfaces having electrophilic active surface centres is possible.

According to a further embodiment of the platelet, the chemical compounds also have a middle group in addition to the anchor group and to the head group, which is arranged between the anchor group and the head group. For example, the middle group can be covalently bonded directly to the anchor group on the one hand and to the head group on the other hand. However, it is also possible that, between the middle group and the anchor group, there is, for example, an oxygen or a sulphur atom or another bridge atom via which the bonding takes place. The same applies for the bond between the middle group and the head group.

The selection of suitable middle groups makes it possible to achieve particularly densely packed and ordered layers. For example, particularly compact self-assembling monolayers can thus be achieved.

In addition, the inventors have recognized that it is possible, for example, to use a highly fluorinated alkyl radical (e.g., an alkyl radical in which more than 50% of the H atoms are replaced by F atoms, preferably more than 75% of the H atoms are replaced by F atoms), in particular a perfluorinated alkyl radical, as the head group, while it is sufficient for the middle group to use conventional alkyl radicals without fluorination or only with partial fluorination. However, it is also possible for the middle group to also contain perfluorinated alkyl radicals.

According to a further embodiment, the middle group is selected from a group comprising linear alkyls, linear fluorinated alkyls, polyethylene glycol, polyethylene diamine, siloxanes and silanes. The middle group preferably has between 1 and 100 carbon atoms or silicon atoms in the backbone of the middle group, in particular between 1 and 50, further preferably between 1 and 20, particularly preferably between 1 and 10 and most preferably between 1 and 5 carbon atoms or silicon atoms. The middle group can have, for example, the general formula —(CH₂)ₘ— or —(SiH₂)ₘ— (where m=1 to 100, in particular m=1 to 50, preferably m=1 to 20, further preferably m=1 to 10, most preferably m=1 to 5).

However, it is also possible, that the middle group is a siloxane group of the general formula —(O—SiR^{q}R^{p})ₘ—, wherein m can assume the same values as just described for alkyl-based middle groups, and wherein R_{q} and Rₚ may be hydrogen or short-chain alkyl radicals, for example, methyl or ethyl. In addition, R^{q} and R^{p} can each be a phenyl radical independently of one another.

According to a further embodiment, the chemical compounds can be at least partially removable from the silicone. Thus, for example, the monolayer formed by the chemical compounds can at least be partially removed again, for example, by a plasma process, and thus the original adhesion of the silicone surface can be restored. The reduction of the adhesion of the at least one surface of the platelet is thus reversible, meaning that the shielding effect and thus the chemical inertness on the surface caused by the chemical compounds, in particular the head groups, can be reversed. For this purpose, a residue-free removal is generally not decisive. A removal of the shielding effect can be achieved, for example, by removing the fluorine-containing head groups. The restoration of the adhesion leads to good boundability or adhesion possibility on the surface and can, when the platelet is arranged at its operation site in an optoelectronic device, be used to apply one or more further components, for example, further encapsulation material or an optical system (for example, a lens) to the platelet and, if necessary, to adhesively bond it. Due to the recovered adhesion, an adhesive or an encapsulation material applied thereto adheres well to the surface may optionally form covalent bonds or bonds via hydrogen bridges with the surface if the chemical compounds are at least partially removed.

According to one embodiment, the platelet can furthermore contain a material selected from a group comprising conversion substances, diffusion particles, fillers and mixtures thereof. For example, the platelet can contain at least one conversion substance and be formed as a conversion platelet or contain diffusion particles and be formed as a diffuser layer. It can thus be used as a conversion platelet or as a diffuser layer in an optoelectronic device, for example, an LED. The conversion platelet or the diffuser layer can be on account of the reduced stickiness applied particularly well to at least one surface, for example, an active layer stack, without leaving any impressions on the platelet due to tools used. Furthermore, the reduced adhesion prevents a change in the optical properties of the conversion platelet or of the diffuser layer as well as visual changes, for example, by adhering particles.

The invention further relates to a method for producing an optoelectronic device. The method comprises the steps: A) providing a device comprising a substrate and an active layer stack on the substrate, B) providing a platelet according to one of the above-mentioned embodiments containing a silicone, C) applying of the platelet on the active layer stack, and D) completing the optoelectronic device.

The active layer stack is electrically contacted during method step A) or in a method step A1) following method step A) or method step C).

The method is used to produce an optoelectronic device containing the platelet described above. Thus, all of the features mentioned in relation to the platelet are also disclosed for the method for producing the optoelectronic device and vice versa. The optoelectronic device produced by the method can be, for example, an LED.

The optical properties of the device are thus not impaired by the chemical compounds on the surface of the platelet, since none or only a few particles adhere to the surface of the platelet, and the thickness of the layer of the chemical compounds is so small that the transparency is maintained. Furthermore, the surface of the platelet has no or only slight impressions, since low suction or pressing forces are necessary during the processing and fitting thereof.

According to one embodiment, the step B) comprises the substeps B1) providing chemical compounds comprising at least one anchor group and one head group, and B2) reaction of the anchor group of the chemical compounds with silicone on at least one surface of the platelet, wherein the adhesion to the at least one surface is reduced by the head groups of the chemical compounds.

Such a method thus makes it possible to reduce the stickiness, that is to say the particle adhesion or the coefficient of friction of the platelet used in the optoelectronic devise. This simplifies the processing, in particular the mounting of the platelet and the production of the optoelectronic device. Furthermore, the method for providing the platelet can be carried out with lower technical effort and, compared to conventional methods for reducing stickiness, at lower costs.

In method step B2), a covalent bond is formed between the anchor group and the silicone surface. Covalent bonds allow directed and particularly stable attachment of the chemical compounds.

According to a further embodiment of the method, the at least one surface is subjected to a pre-treatment before the method step B2). Pre-treatment refers here to a surface treatment or surface functionalization. The type of pre-treatment is based on the nature of the substrate, that is to say the properties of the respective silicone, and to the nature of the anchor group of the chemical compound. Examples of pre-treatments can be UV radiation or a treatment by plasma.

The inventors of the present invention have been found, the density of the chemically active surface centres can be significantly increased by a pre-treatment of a silicone surface. By means of UV radiation and/or plasma treatment, chemical bonds on the surface of the silicone can be broken and highly reactive or metastable groups such as, for example, radicals or hydroperoxides can be produced. They increase the reactivity of the silicone surface and can either itself react with the anchor group of the chemical compounds or react further to form functional groups on the silicone surface (e.g., hydroxyl groups). In this way, more functional groups are available on the surface of the silicone for a reaction with the anchor group of the chemical compounds. In this way, a higher density of the chemical compounds can be achieved on the surface of the platelet, a more compact layer can be produced, and the adhesion or adhesiveness can be further reduced.

According to a further embodiment of the method, the pre-treatment can be carried out with a plasma. Particularly suitable plasmas are, for example, oxygen plasma, argon plasma and NH₃-plasma or plasma from mixtures of these gases. However, other conventional plasma treatments can also be used. For large-area or industrial applications, the use of atmospheric plasma with air as process gas is also suitable, provided no oxidation-sensitive surfaces are present.

The inventors of the present invention have been found, the use of an oxygen plasma can significantly increases the density of the chemically active surface centres on the silicone surface, in particular of silicone surface-OH and silicone surface-OOH, but also silicone surface-R^{C}—COOH (wherein R^{C} is an alkyl group, e.g., methylene). In this way, significantly more chemical compounds can be bonded to the silicone surface, which leads to a stronger adhesion reduction.

Nitrogen-containing surface centres, for example, the above-mentioned centres, silicone surface-NY₂ can be produced by NH₃-plasmas. Such centers are suitable, for example, for bonding anchor groups based on isocyanates.

The inventors of the present invention also have recognized that the density of the active chemical surface centres on the silicone surface can also be increased by the method according to the invention without oxidizing plasmas. For example, plasmas of hydrogen or mixtures of hydrogen and argon are suitable. Inert gas plasmas can also be used. In particular, plasmas of noble gases such as argon plasma or helium plasma are suitable.

According to a further embodiment of the method, the method step B2) is carried out with a method selected from a group comprising dip coating, spray coating, spin coating, vapor deposition, in particular chemical vapor deposition (CVD). The use of plasma-enhanced chemical vapor deposition (PECVD) is also conceivable.

The reaction of the anchor group with the silicone surface in the context of a dip, spin or spray coating can lead to a reliable layer or film formation and thus to a reduction in the adhesion. At the same time, these methods are suitable for use on an industrial scale. In particular, dip, spin and spray coating are suitable for chemical compounds which are difficult to evaporate.

The vapor deposition is suitable for the deposition of chemical compounds that can be transferred into the gas phase without decomposing, and is particularly suitable for the industrial scale. It allows rapid and cost-effective production of the platelet.

Overall, method step B), that is to say providing the coated platelet, can be carried out comparatively inexpensively.

According to a further embodiment, in method step C), the platelet is applied to the active layer stack in such a way that the surface, on which the chemical compounds are present, is arranged on the side of the platelet which faces away from the active layer stack. Thus, on the one hand, the stickiness of the silicone of the non-coated surface can be utilized for the adhesion of the platelet to the active layer stack, on the other hand, the surface on which the chemical compounds are present develops, on the side of the platelet facing away from the active layer stack, the already mentioned advantages. In particular, the mounting of the active layer stack with the platelet is facilitated, since the adhesion on the surface of the platelet is reduced and thus sticking of the platelet to the placement tool is prevented. Furthermore, suction or pressing forces can be reduced and thus impressions in the platelet can be prevented. As a result, the optical properties of the platelet or the later device are not impaired and no visual changes occur on the platelet. On the tool side, special surfaces, such as a teflon coating or a roughening, can also be dispensed with, since the adhesion to the tool is already reduced by the chemical compounds on the surface of the platelet.

According to a further embodiment of the method, the method step D) comprises sealing the active layer stack and the platelet. In this case, for example, the active layer stack and the platelet arranged thereon can be encapsulated by injection molding with a casting material, in particular by “foil assisted molding”. Due to the reduced stickiness of the surface of the silicone platelet, the spray flash can be reduced, or a spray flash produced can be removed more easily.

Due to the reduced stickiness or adhesion of the surface of the platelet facing away from the layer stack, it is further prevented that a sealing material applied in the method step D), for example, a casting, is arranged on said surface. Rather, an overflow and accumulation of casting material on the surface can be prevented. The optical properties of the platelet are thus preserved even after the sealing. A flash which may still be produced can be removed more easily from the surface of the platelet due to lower adhesion to the platelet.

According to a further embodiment, the method step D) can comprise the substeps D1) at least partially removing the chemical compounds and D2) applying at least one further component of the optoelectronic device to the platelet. The component can be, for example, an encapsulation and/or an optical system, in particular a lens. The substeps D1) and D2) can be effected in addition to the sealing of the active layer sequence and of the platelet, in particular after the active layer sequence and the platelet have been sealed. Alternatively, the substeps D1) and D2) can also be performed without sealing the active layer sequence and the platelet.

Thus, the chemical compounds can be at least partially removed from the surface of the platelet facing away from the layer stack and thus the original stickiness of the silicone can be at least partially restored. The chemical compounds on the surface of the silicone are thus a reversible coating of the silicone. After the at least partial removal of the chemical compounds and their shielding effect, the restored adhesion and thus the wettability or adhesion possibility on the surface can be utilized for arranging a further component such as an encapsulation and/or an optical system, such as, for example, a lens, on the platelet and, in the case of a further component, to be fixed with adhesive. Good adhesion is made possible by the re-established adhesion possibility or wettability.

According to one embodiment, method step D1) can be carried out by a plasma process. The plasma can be selected from an argon plasma, hydrogen plasma, oxygen plasma or mixtures thereof. Depending on the nature of the chemical compounds to be removed or the head groups thereof, other gases can also be selected, in order to avoid negative influences on the silicone or the device located underneath. In particular, method step D1) can be carried out using an argon plasma process.

Alternatively or additionally, the removal of the chemical compounds in method step D1) can also be performed by UV radiation and/or wet-chemical.

The invention further relates to an optoelectronic device comprising a substrate, an active layer stack on the substrate, electrical contacts and a platelet according to the above-mentioned embodiments on the active layer stack. Such a device can be produced, for example, using a method according to the above-mentioned embodiments. All of the features mentioned in connection with the platelet and with the method thus also apply to the optoelectronic device and vice versa.

The platelet is arranged on the active layer stack in such a way that the surface, on which chemical compounds are present and thus the adhesion is reduced, is on the side of the platelet facing away from the active layer stack.

The optoelectronic device can furthermore have a casting which laterally surrounds the active layer stack and the platelet. Due to the reduced stickiness or wettability on the surface of the platelet facing away from the active layer stack, no or only a small amount of casting material is present on the surface of the platelet. If necessary, this can be removed again easily since the adhesion to the surface of the platelet is low. As a result, the optical properties such as brightness and emission characteristic of the device are not impaired.

Alternatively, the optoelectronic device can have an encapsulation which is arranged on the substrate and encloses the layer stack and the platelet. Furthermore, the encapsulation can have, for example, the shape of a window or a lens. Such an encapsulation can, for example, contain glass and/or plastic as material or consist of glass and/or plastic.

A casting or an encapsulation can protect the electrical contacts, for example, bonding wires, of the device and the platelet from mechanical action.

The optoelectronic device can be, for example, a light-emitting diode (LED). The platelet can be used as a conversion platelet in the optoelectronic device. For this purpose, it can comprise one or more conversion substances in addition to the silicone.

The optoelectronic device can furthermore be suitable for use in a superordinate device. For example, the surface of the platelet on which the chemical compounds are present can be treated by a plasma process in such a way that the chemical compounds are largely removed. An additional component can be arranged by the thus obtained recovered stickiness or bondability of the surface of the platelet, for example, an encapsulation or an optical system such as, for example, a lens, can be arranged on the platelet. The adhesion then takes place at least partially over the sticky surface of the platelet or via an adhesive, which can adhere well to the surface of the platelet.

### BRIEF DESCRIPTION OF THE DRAWINGS

In the following, a platelet, a method for producing an optoelectronic device and an optoelectronic device described here are explained in more detail with reference to the figures.

FIG. 1 shows a schematic side view of an exemplary embodiment of a platelet;

FIG. 2 shows the structure of a monomolecular layer on a platelet according to an exemplary embodiment;

FIGS. 3a to 3d show exemplary embodiments of a method for producing an optoelectronic device;

FIG. 4a shows the schematic side view of an exemplary embodiment of a platelet and a mounting device;

FIGS. 4b and 4c show images of a plan view of a reference platelet after the mounting process; and

FIGS. 5a to 5c show images of differently treated silicone surfaces.

In the exemplary embodiments and figures, equal, identical or identically operating elements can in each case be provided with the same reference symbols. The elements illustrated and their size relationships among one another are not to be regarded as true to scale; rather, individual elements, such as, for example, layers, components, devices, and regions, can be represented with an exaggerated size for better representability and/or for a better understanding.

### DETAILED DESCRIPTION OF ILLUSTRATIVE EMBODIMENTS

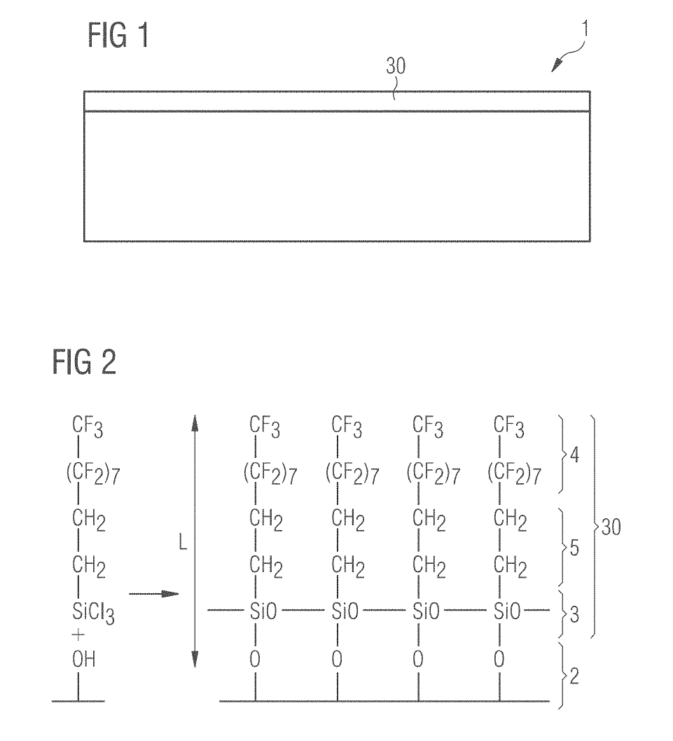

FIG. 1 shows the schematic side view of a platelet according to an exemplary embodiment. The platelet 1 has a layer 30 on one of its surfaces. The platelet 1 comprises a silicone and can, if it is to be used, for example, as a conversion layer in a device, also contain a conversion substance or a plurality of conversion substances and other fillers. The layer 30 contains chemical compounds which are covalently bonded to the surface of the silicone. The chemical compounds each comprise an anchor group 3, a head group 4 and optionally a middle group 5. The chemical compounds are bonded to the silicone of the platelet 1 by the anchor group 3 and form a monomolecular layer 30. The latter can therefore have a thickness of, for example, 10 nm.

The chemical compounds reduce the adhesion on the surface of the platelet 1 by the head groups 4. This significantly reduces contamination of the platelet 1 by adhering particles to the surface of the platelet 1. Furthermore, the reduced adhesion facilitates handling of the platelet 1 during processing. In particular, when the platelet 1 comes into contact with the tool, such as, for example, a vibrating conveyor, a sorter, a taper or during the mounting process, an adherence of the platelet 1 to the respective tool is avoided and, in addition, the suction and pressing force can be reduced during mounting, such that impressions on the platelet are prevented or greatly reduced.

If the platelet 1 is inserted into an optoelectronic device and sealed at or on the platelet 1, for example, by injection molding, the accumulation of undesirable residues or flashes can be prevented and thus the optical properties such as brightness and emission characteristic of the device are obtained. For this purpose, the platelet is arranged in such a way that the surface having the chemical compounds faces away from the active layer stack of the device. Any residues of, for example, casting material that are present on the surface of the platelet 1 can be removed very easily due to the low adhesion to the surface.

The reduction of the silicone stickiness of the surface of the platelet is effected, for example, by the bonding of fluorocarbon chains with the aid of a silyl anchor function. The connection can be carried out, for example, wet-chemically with the dipping method with a diluted solution. In tests for testing the stickiness, in particular the particle adhesion, a significant reduction of the particle number compared to the untreated silicone surface can be detected. This can be explained by the formation of a SAM which shields the sticky silicone surface.

In addition, the layer 30 can be at least partially or completely removable from the platelet 1, so that the original adhesion or wettability or bondability of the silicone in the platelet 1 can be restored. This is advantageous if the platelet 1 is used in an optoelectronic device and after processing and, if necessary, sealing, a further component such as, for example, an encapsulation or an optical system is to be applied to the platelet 1. After the layer 30 has been removed, the stickiness of the silicone can be used to adhere the encapsulation or an adhesive for the adhesion of the optical system. The layer 30 can be removed, for example, by a plasma process.

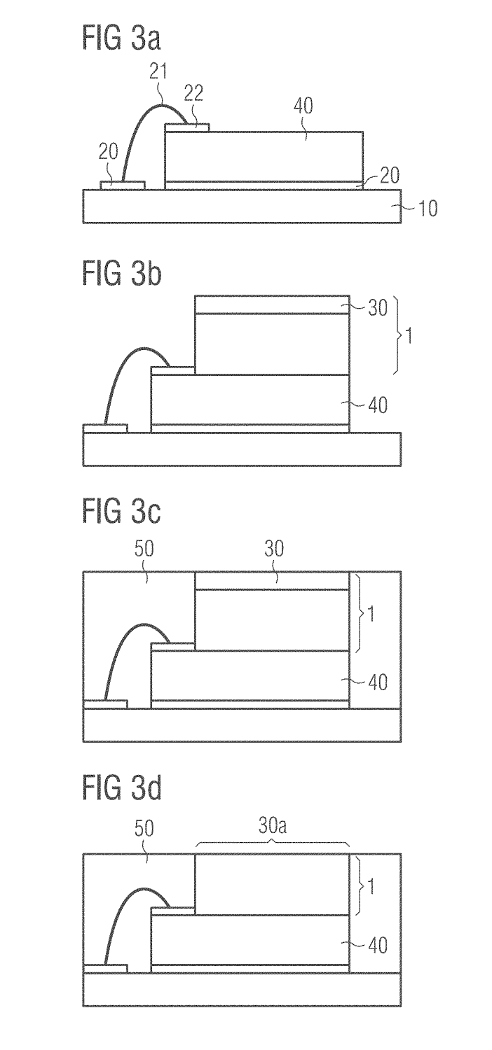

FIG. 2 shows the chemical structure of such a layer 30 on the basis of an exemplary embodiment. A hydroxyl group is shown on the left of the image, as an example of a chemically active surface centre on the silicone surface (indicated here as a line) of the platelet 1. Furthermore, an example of a chemical compound for bonding to the silicone surface is shown on the left. The latter has a silyl anchor group 3, a CH₂CH₂ group as a middle group 5, and a (CF₂)₇CF₃ group as head group 4. The active surface centre, which in this example is a hydroxyl group, can be produced in a pre-treatment of the platelet, for example, by of UV radiation or a plasma treatment on the surface of the platelet.

In the method for producing or providing a platelet 1 on the surface of which chemical compounds are present, the silyl anchor group reacts with the hydroxyl group on the silicone surface. In addition, it is also possible that, depending on the anchor group 3, bonds with adjacent anchor groups 3 are also formed. This is shown, for example, on the right-hand side in the figure. The anchor group 3 of the chemical compound is bonded to the silicone via the oxygen by a covalent bond 2. The head groups 4 can either be bound directly to the anchor groups 3, but it is also possible, that a middle group 5 is arranged between the anchor group 3 and the head group 4, as shown, for example, in FIG. 2. The chemical compounds can together form a layer 30 which can also be referred to as a film.

Due to the directed bonding via covalent bonds to the silicone surface by chemisorption, no multiple layers are formed, that is to say no multilayers, but at most a single layer, that is to say a monolayer, is achieved. For a significant reduction of the stickiness, however, it is not necessary, that a complete monomolecular covering of the silicone surface with the chemical compounds is achieved, but also a lower degree of coverage can already lead to the desired effect of the reduced adhesion. The anchor, middle and head groups 3, 4 and 5 shown in FIG. 2 are only one exemplary embodiment. In this case, the thickness L of the layer 30 is approximately 1 nm.

During the production of the layer 30 on the silicone surface, the anchor group 3 of the chemical compounds reacts with the silicone at least in regions of the surface of the platelet 1. For example, fluorocarbon chains can be bonded to the silicone surface with the aid of a silyl anchor function. The fluorocarbon chains can be applied as a diluted solution, for example, in a wet-chemical dipping method. The application by a gas phase method such as CVD or PECVD is likewise conceivable. A chemical compound which can be applied by CVD is, for example, 1H,1H,2H,2H-perfluorodecyltrichlorosilane. For example, 1-metoxy-2-propanol can be applied by a dip coating and be bonded to the silicone surface as a hydrolyzed silane.

In a test for testing the particle adhesion, a significant reduction of the particle number after such a coating compared to an untreated reference sample can be detected. This can be explained by the formation of a SAM which shields the sticky silicone surface.

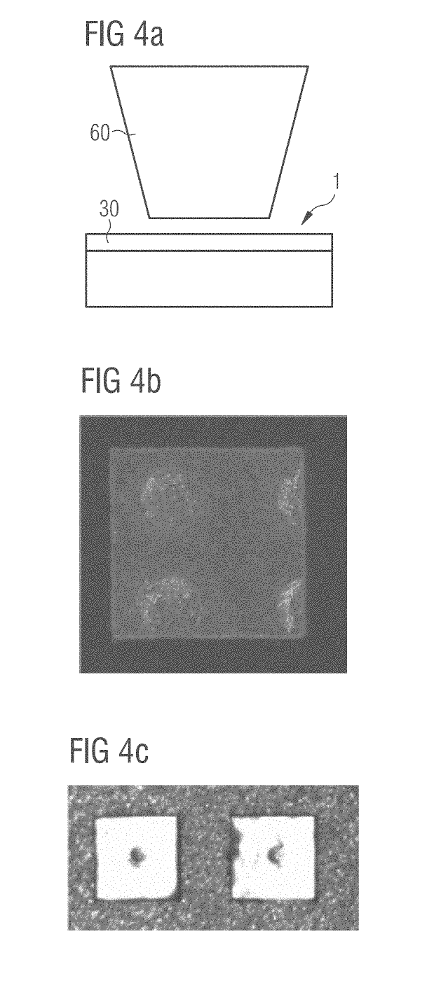

FIGS. 3a to 3d show schematic side views of a method for producing an optoelectronic device on the basis of an exemplary embodiment. The device shown in FIGS. 3a to 3d is, for example, an LED.

FIG. 3a shows the method step A) in which a device is provided which comprises a substrate 10, an active layer stack 40 on the substrate 10 and electrical contacts, here shown as metallizations 20 and 22 as well as bonding wire 21.

Method step B) has already been explained in conjunction with FIG. 2, namely providing a platelet 1, which contains a silicone, and a layer 30 on a surface. Of course, platelets 1, which additionally contain a conversion substance, can also be used. Furthermore, all combinations of the above-described anchor 3, middle 5 and head groups 4 are possible as chemical compounds.

FIG. 3b shows the method step C) in which the platelet 1 is applied to the active layer stack 40. The platelet 1 can be fixed on the active layer stack 40, for example, using an adhesive, in particular a silicone. In this case, it is to be noted that the layer 30 is arranged on the side of the platelet 1 which faces away from the layer stack 40. For the sake of clarity, the remaining reference characters are no longer shown in FIG. 3b. In this regard, reference is made to FIG. 3a.

FIGS. 3c and 3d show method step D) in which the optoelectronic device is completed. According to FIG. 3c, the platelet 1 with the layer 30 and the active layer stack 40 is sealed. For this purpose, according to the exemplary embodiment of FIG. 3c, a casting 50 is applied around the platelet 1 and the active layer stack, for example, by injection molding or casting. As a result of the layer 30 having a low adhesion or wettability, a running of the casting 50 onto the platelet 1 is avoided or prevented. As a result, the spray flash is reduced. If, nevertheless, an excess of casting material 50 is produced on the layer 30, it can easily be removed again, since only a slight adhesion is present on the platelet 1 or the layer 30 thereof.

As an alternative to the method step in FIG. 3c or also in addition thereto, the layer 30 can be at least partially removed again by, for example, a plasma process. According to FIG. 3d, this step is shown by way of example after sealing using a casting 50. The surface of the platelet 1, which faces away from the layer stack 40, is thus no longer covered by the layer 30, but rather has a surface 30a which has the original stickiness or bondability of the silicone. At least one further component can now be applied to this sticky surface 30a, such as an encapsulation and/or an optical system such as, for example, a lens, and can also be fastened using the possibility of adhesion of the surface 30a, for example, by an adhesive. Here, the reversibility of the coating 30 on the platelet 1 is utilized.

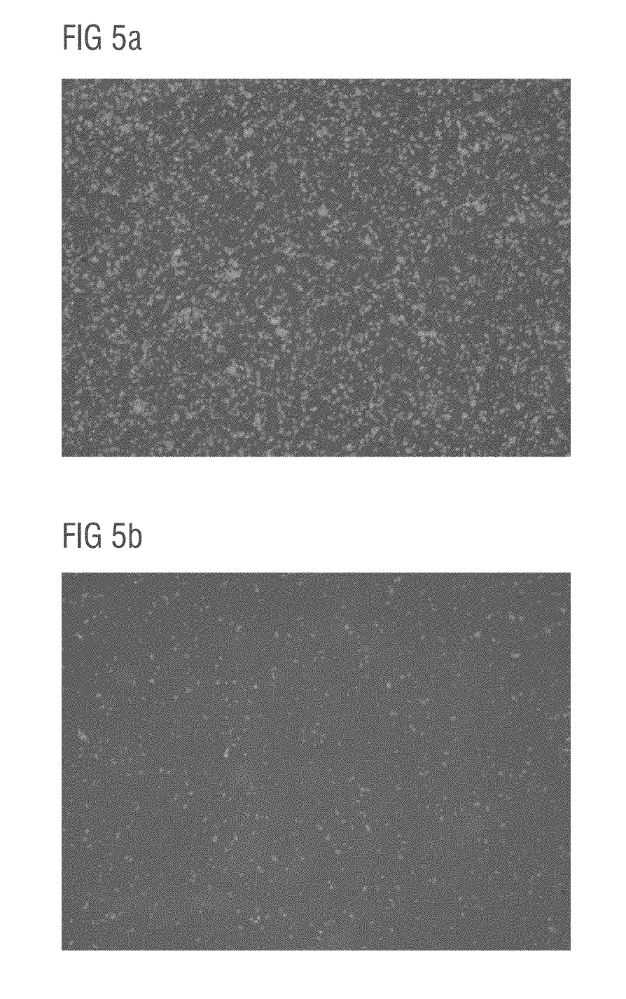

FIG. 4a shows a schematic side view of a mounting tool 60 above a platelet 1 with the layer 30. The platelet 1 is sucked in by the tool 60, is transported to the desired location and is pressed there. By virtue of the fact that the layer 30 reduces the adhesion to the platelet 1, reduced suction and pressing forces can be used, as a result of which the platelet 1 can be used largely or completely without damage at the target site. In the case of use in an optoelectronic device such as, for example, an LED, this is particularly important for maintaining the brightness and emission characteristic of the device.

FIGS. 4b and 4c show images of a top view of a reference platelet, which has no coating 30 according to the invention and has been processed by a mounting tool 60. The mounting tool 60 had a roughening or a special shape for reducing the adhesion of the silicone platelets. Due to the high stickiness of the silicone platelet, impressions of the tool 60 on the silicone platelet are clearly visible, caused by the high suction and pressing forces.

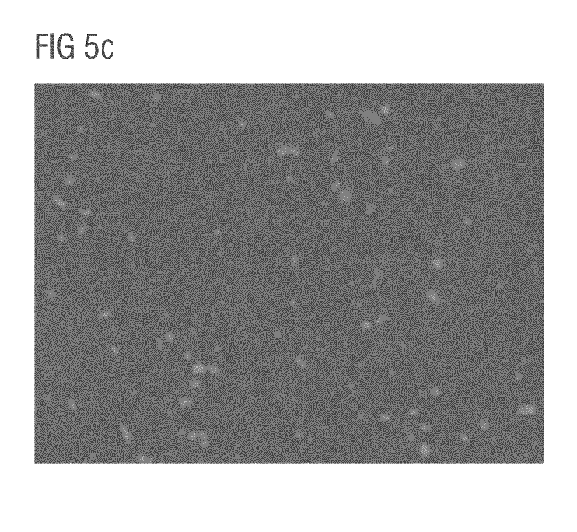

FIGS. 5a to 5c show images of top views of silicone surfaces which are untreated or are treated according to the invention.

FIG. 5a shows a reference surface which is untreated and accordingly has a high degree of stickiness. In this case, it is possible to clearly identify many particles which adhere to the reference surface.

FIG. 5b shows a silicone surface which has a layer 30 which contains the chemical compounds. Here, the number of particles on the surface is clearly reduced compared to FIG. 5a. In FIG. 5c, an enlargement of the FIG. 5b, it can also be seen, that no change of the visual impression on the silicone surface has occurred due to the coating with the layer 30, which enables the use of the platelet 1 in an optoelectronic device.

The invention is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

1-20. (canceled)

21. A platelet for an optoelectronic device comprising:
silicone; and
chemical compounds located on at least one surface of the platelet,
wherein each chemical compound comprises an anchor group and a head group,
wherein the chemical compounds are bonded to the silicone by the anchor group, and
wherein an adhesion on the at least one surface is reduced by the head groups of the chemical compounds.

22. The platelet according to claim 21, wherein the chemical compounds bonded to the silicone by the anchor group form a monomolecular layer.

23. The platelet according to claim 21, wherein the chemical compounds bonded to the silicone by the anchor group form a self-assembling monolayer.

24. The platelet according to claim 21, wherein the head group is selected from the group consisting of linear alkyl groups, branched alkyl groups, at least partially fluorinated linear alkyl groups, at least partially fluorinated branched alkyl groups, perfluorinated linear alkyl groups and perfluorinated branched alkyl groups.

25. The platelet according to claim 21, wherein the anchor group of the chemical compounds is bonded to the silicone by a covalent bond.

26. The platelet according to claim 21, wherein the anchor group of the chemical compounds is selected from the group consisting of: 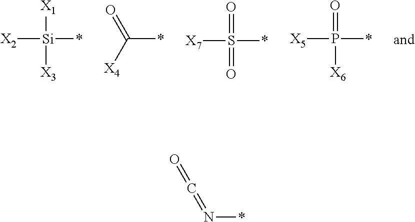
wherein X₁ to X₃ are selected independently of one another from the group consisting of —Cl, —Br, —I, —OH, —OR₁, —H, and —R₁,
wherein at most two of X₁ to X₃ are —H or R₁, wherein R₁ is an alkyl,
wherein X₄ is selected from the group consisting of —Cl, —Br, —I, —OH, —H, and —OSiX₁X₂X₃,
wherein X₅ and X₆ are selected independently of one another from the group consisting of —Cl, —Br, —I, —OH, —OR₁, and —H, and
wherein X₇ is selected from the group consisting of —Cl, —Br, —I, —OH, and —OR₁.

27. The platelet according to claim 21, wherein the chemical compounds further contain a middle group arranged between the anchor group and the head group.

28. The platelet according to claim 27, wherein the middle group is selected from the group consisting of linear alkyls, linear fluorinated alkyls, polyethylene glycol, polyethylene diamine, siloxanes and silanes.

29. The platelet according to claim 21, wherein the chemical compounds are at least partially removable from the silicone.

30. The platelet according to claim 21, further comprising a material selected from the group consisting of conversion substances, diffusion particles, fillers and mixtures thereof.

31. A method for producing an optoelectronic device, the method comprising:
providing a substrate and an active layer stack disposed on the substrate;
providing the platelet according to claim 21 containing the silicone;
applying the platelet on the active layer stack, wherein the active layer stack is electrically contacted during or after providing the substrate and the active layer stack, or after applying the platelet on the active layer stack; and
completing the optoelectronic device.

32. The method according to claim 31, wherein providing the platelet comprises:
providing the chemical compounds comprising the anchor groups and the head groups; and
reacting the anchor groups of the chemical compounds with the silicone on at least one surface of the platelet such that an adhesion to the at least one surface is reduced by the head groups of the chemical compounds.

33. The method according to claim 32, further comprising subjecting the at least one surface to a pre-treatment before reacting the anchor groups of the chemical compounds with the silicone on the at least one surface of the platelet.

34. The method according to claim 33, wherein the pre-treatment is carried out with a plasma.

35. The method according to claim 32, wherein reacting the anchor groups with the silicone is carried out with dip coating, spray coating, spin coating or vapor deposition.

36. The method according to claim 31, wherein completing the optoelectronic device comprises sealing the active layer stack and the platelet.

37. The method according to claim 31, wherein completing the optoelectronic device comprises:
at least partially removing the chemical compounds; and
applying at least one further component of the optoelectronic device to the platelet.

38. The method according to claim 37, wherein at least partially removing the chemical compound includes a plasma process.

39. An optoelectronic device comprising:
a substrate;
an active layer stack disposed on the substrate;
the platelet according to claim 21 disposed on the active layer stack; and
electrical contacts.

40. The optoelectronic device according to claim 39, further comprising:
a casting laterally surrounding the active layer stack and the platelet; or
an encapsulation arranged on the substrate and surrounding the active layer stack and the platelet.
